(19) United States
(12) Patent Application Publication
(10) Pub. No.: US 2026/0255614 A1
(43) Pub. Date: Aug. 27, 2026

(54) MEMORY DEVICE, MANUFACTURING METHOD THEREOF, AND MEMORY SYSTEM

(71) Applicant: Yangtze Memory Technologies Co., Ltd., Wuhan (CN)

(72) Inventors: Xikai Sun, Wuhan (CN); Xu Hou, Wuhan (CN); Bin Liao, Wuhan (CN)

(21) Appl. No.: 19/240,275

(22) Filed: Jun. 17, 2025

(30) Foreign Application Priority Data
Feb. 26, 2025 (CN) 202510220603.0

(51) Int. Cl. H10B 80/00; H10W 90/00; H10W 80/00

(52) U.S. Cl. CPC H10B 80/00; H10W 90/00; H10W 80/312; H10W 80/327; H10W 90/792

(57) ABSTRACT

The present disclosure provides a memory device and a manufacturing method thereof, and a memory system. The memory device comprises: a first semiconductor structure comprising a memory cell array, a first interconnection layer and a first bonding layer in contact with the first interconnection layer; a second semiconductor structure comprising a second interconnection layer and a second bonding layer; and first connection structures; wherein the memory cell array is located in the first semiconductor structure, the first interconnection layer comprises first power lines, and the first power line is at least partially located in the first semiconductor structure; and the second interconnection layer comprises second power lines; the first connection structure extends through the first bonding layer and the second bonding layer and connects with the first power line and the second power line.

### CROSS-REFERENCE TO RELATED APPLICATIONS

This application claims the benefit of priority to Chinese Application No. 202510220603.0, filed on February 26, 2025, which is hereby incorporated by reference in its entirety.

### FIELD OF TECHNOLOGY

The present disclosure relates to the field of semiconductor technology, and in particular, to a memory device, a manufacturing method thereof, and a memory system.

### BACKGROUND

Semiconductor memory, as a basic component of electronic systems, is one of the most widely used electronic devices in modern information industry. Dynamic Random Access Memory (DRAM) is used as a high-density volatile memory and is widely used in markets such as smart phones, computers and servers. With the development of artificial intelligence, high-performance computing, and the like, the DRAM industry is exploring new storage structures.

### SUMMARY

According to one aspect of the present disclosure, a memory device is provided. The memory device may include a first semiconductor structure including a memory cell array, a first interconnection layer and a first bonding layer disposed along a first direction. The first interconnection layer may be in contact with the first bonding layer, and the first direction may be perpendicular to a plane where the first interconnection layer is located. The memory cell array may be located in a memory area of the first semiconductor structure, the first interconnection layer may include first power lines extending along a second direction, each of the first power lines may be at least partially located in a first peripheral area of the first semiconductor structure, and the memory area and the first peripheral area may be arranged along the second direction. The memory device may include a second semiconductor structure including a second bonding layer and a second interconnection layer sequentially stacked along the first direction and in contact with each other. The second bonding layer may be further in contact with the first bonding layer, the second interconnection layer may include second power lines extending along a third direction, and the third direction may intersect with the second direction. The memory device may include first connection structures. Each of the first connection structures may extend through the first bonding layer and the second bonding layer along the first direction, and two ends of each of the first connection structures may be connected to the first power line and the second power line respectively.

In some implementations, a side of the first semiconductor structure away from the first bonding layer may be provided with power pads. In some implementations, the power pads may be coupled to the first power lines.

In some implementations, each of the first connection structures may include a first bonding contact located in the first bonding layer and a second bonding contact located in the second bonding layer. In some implementations, the first bonding contact may be bonded with the second bonding contact. In some implementations, the first bonding contact may be in contact with at least one of the first power lines, and the second bonding contact may be in contact with at least one of the second power lines.

In some implementations, the first semiconductor structure may include a first memory area and a second memory area disposed at an interval along the second direction, and the first peripheral area may be located between the first memory area and the second memory area. In some implementations, the first power line may penetrate through the first peripheral area along the second direction.

In some implementations, in the first semiconductor structure, a third interconnection layer adjacent to the first interconnection layer may include third power lines extending along the third direction and located in the first peripheral area. In some implementations, the third power lines may be coupled to the first power lines. In some implementations, a number of the third power lines may be less than a number of the first power lines, and the number of the third power lines may be less than a number of the second power lines.

In some implementations, the first semiconductor structure may further include a redistribution layer located between the power pads and the memory cell array. In some implementations, the redistribution layer may be disposed in the memory area and the first peripheral area and may be coupled to the power pads and the third power lines.

In some implementations, the second semiconductor structure may include a second peripheral area and a driving circuit area arranged along the second direction, the second peripheral area may correspond to the first peripheral area, and the driving circuit area may correspond to the memory area. In some implementations, the second power lines may be located in the second peripheral area.

In some implementations, the first semiconductor structure may include a first memory area and a second memory area, and the first peripheral area may be located between the first memory area and the second memory area. In some implementations, the second semiconductor structure may include a first driving circuit area and a second driving circuit area, and the second peripheral area may be located between the first driving circuit area and the second driving circuit area.

In some implementations, the second interconnection layer may further include a fourth power line extending along the second direction, and the fourth power line may be at least partially located in the driving circuit area. In some implementations, the fourth power line may have a first end and a second end disposed opposite to each other along the second direction, and the first end may be close to the second peripheral area. In some implementations, the first end may be coupled to at least one of the first power lines through a second connection structure, and the second connection structure may extend through the first bonding layer and the second bonding layer along the first direction and may be disposed at an interval with the first connection structure.

In some implementations, in the second semiconductor structure, a fourth interconnection layer adjacent to the second interconnection layer may include a fifth power line extending along the second direction. In some implementations, the fifth power line may be at least partially located in the first peripheral area, and the fifth power line may be coupled to the second power lines through a first interconnection access.

In some implementations, the first end of the fourth power line may be coupled to the fifth power line through a second interconnection access.

In some implementations, the fourth interconnection layer may further include a sixth power line extending along the third direction and located in the driving circuit area. In some implementations, the sixth power line may be coupled to the fourth power line through a third interconnection access.

In some implementations, at least one of a sense amplifier, a word line driver, a row decoder and a column decoder may be disposed in a substrate of the second semiconductor structure and may be located in the driving circuit area and coupled to the sixth power line.

In some implementations, the second interconnection layer may further include signal lines located in the driving circuit area. In some implementations, each of the signal lines may be coupled to one of the sense amplifier, the word line driver, the row decoder and the column decoder. In some implementations, the first interconnection layer may further include lead-out structures arranged in an array and located in the memory area. In some implementations, each of the lead-out structures may be coupled to one bit line or one word line of the memory cell array. In some implementations, each of the lead-out structures may be coupled to at least one of the signal lines through a third connection structure, and the third connection structure may extend through the first bonding layer and the second bonding layer along the first direction and is disposed at an interval with the first connection structure.

In some implementations, the memory cell array includes a dynamic random access memory cell array.

According to another aspect of the present disclosure, a memory system is provided. The memory system may include at least one memory device. The at least one memory device may include a first semiconductor structure including a memory cell array, a first interconnection layer and a first bonding layer disposed along a first direction. The first interconnection layer may be in contact with the first bonding layer, and the first direction may be perpendicular to a plane where the first interconnection layer is located. The memory cell array may be located in a memory area of the first semiconductor structure, the first interconnection layer may include first power lines extending along a second direction, each of the first power lines may be at least partially located in a first peripheral area of the first semiconductor structure, and the memory area and the first peripheral area may be arranged along the second direction. The at least one memory device may include a second semiconductor structure including a second bonding layer and a second interconnection layer sequentially stacked along the first direction and in contact with each other. The second bonding layer may be further in contact with the first bonding layer, the second interconnection layer includes second power lines extending along a third direction, and the third direction may intersect with the second direction. The at least one memory device first connection structures. Each of the first connection structures may extend through the first bonding layer and the second bonding layer along the first direction. Two ends of the each of the first connection structures may be connected to the first power line and the second power line respectively. The memory system may include a memory controller coupled to the memory device and configured to control the memory device to perform an operation.

According to a further aspect of the present disclosure, a method of manufacturing a memory device. The method may include forming a first semiconductor structure. The first semiconductor structure may include a memory cell array, and a first interconnection layer and a first bonding layer disposed along a first direction. The first interconnection layer may be in contact with the first bonding layer, and the first direction may be perpendicular to a plane where the first interconnection layer is located. The memory cell array may be located in a memory area of the first semiconductor structure, the first interconnection layer may include first power lines extending along a second direction, each of the first power lines may be at least partially located in a first peripheral area of the first semiconductor structure, and the memory area and the first peripheral area may be arranged along the second direction. The method may include forming a second semiconductor structure. The second semiconductor structure may include a second bonding layer and a second interconnection layer sequentially stacked along the first direction and in contact with each other. The second interconnection layer may include second power lines extending along a third direction, and the third direction may intersect with the second direction. The method may include contacting the first bonding layer with the second bonding layer. Each of the second power lines may be coupled to at least one of the first power lines through at least one first connection structure, and the first connection structure may penetrate through the first bonding layer and the second bonding layer along the first direction.

In some implementations, the first bonding layer may include a first bonding contact. In some implementations, the second bonding layer may include a second bonding contact. In some implementations, the contacting the first bonding layer with the second bonding layer may include bonding the first bonding contact in the first bonding layer to the second bonding contact in the second bonding layer correspondingly. In some implementations, the first connection structure may include the first bonding contact and the corresponding second bonding contact. In some implementations, the first bonding contact may be in contact with at least one of the first power lines, and the second bonding contact may be in contact with at least one of the second power lines.

In some implementations, the first semiconductor structure may be a first memory area and a second memory area, and the first peripheral area may be located between the first memory area and the second memory area. In some implementations, the forming a first semiconductor structure may include forming, in the first interconnection layer, the first power lines penetrating through the first peripheral area along the second direction.

In some implementations, the forming a first semiconductor structure may further include forming a third interconnection layer adjacent to the first interconnection layer. In some implementations, the third interconnection layer may include third power lines extending along the third direction and located in the first peripheral area. In some implementations, the third power lines may be coupled to the first power lines, a number of the third power lines may be less than a number of the first power lines, and the number of the third power lines may be less than a number of the second power lines.

In some implementations, the second semiconductor structure may include a second peripheral area and a driving circuit area disposed along the second direction, the second peripheral area may correspond to the first peripheral area, and the driving circuit area may correspond to the memory area. In some implementations, the forming a second semiconductor structure may include forming, in the second interconnection layer, the second power lines located in the second peripheral area.

In some implementations, the forming a second semiconductor structure may further include forming a fourth power line extending along the second direction in the second interconnection layer. In some implementations, the fourth power line may be at least partially located in the driving circuit area, the fourth power line may have a first end and a second end disposed opposite to each other along the second direction, and the first end may be close to the second peripheral area. In some implementations, the contacting the first bonding layer with the second bonding layer may include coupling the first end of the fourth power line with the first power line through a second connection structure. In some implementations, the second connection structure may extend through the first bonding layer and the second bonding layer along the first direction and may be disposed at an interval with the first connection structure.

In some implementations, the forming a second semiconductor structure may further include forming a fourth interconnection layer adjacent to the second interconnection layer. In some implementations, the fourth interconnection layer may include a fifth power line extending along the second direction, and the fifth power line may be at least partially located in the first peripheral area. In some implementations, the method may include forming a first interconnection access between the fifth power line and the second power line.

In some implementations, the forming a second semiconductor structure may further include forming a second interconnection access between the first end of the fourth power line and the fifth power line.

In some implementations, the forming a second semiconductor structure may further include forming a sixth power line extending along the third direction in the fourth interconnection layer. In some implementations, the sixth power line may be located in the driving circuit area. In some implementations, the forming a second semiconductor structure may further include forming a third interconnection access between the sixth power line and the fourth power line.

In some implementations, the forming a second semiconductor structure may further include forming at least one of a sense amplifier, a word line driver, a row decoder and a column decoder in a substrate of the driving circuit area. In some implementations, the sixth power line may be coupled to one of the sense amplifier, the word line driver, the row decoder and the column decoder. In some implementations, the forming a second semiconductor structure may further include forming signal lines in the second interconnection layer. In some implementations, each of the signal lines may be located in the driving circuit area and may be coupled to one of the sense amplifier, the word line driver, the row decoder and the column decoder. In some implementations, the forming a first semiconductor structure may further include forming lead-out structures arranged in an array in the first interconnection layer. In some implementations, each of the lead-out structures may be located in the memory area and may be coupled to one bit line or one word line of the memory cell array. In some implementations, the contacting the first bonding layer with the second bonding layer may include coupling each of the lead-out structures to at least one of the signal lines through a third connection structure. In some implementations, the third connection structure may extend through the first bonding layer and the second bonding layer along the first direction and may be disposed at an interval with the first connection structure.

In some implementations, the method may include forming power pads on a side of the first semiconductor structure away from the first bonding layer along the first direction. In some implementations, the power pads may be coupled to the first power lines.

In some implementations, the method may include forming a redistribution layer on a side of the memory cell array away from the first bonding layer before forming the power pads. In some implementations, the redistribution layer may be disposed in the memory area and the first peripheral area and may be coupled to the first power lines in the first interconnection layer and located in the first peripheral area. In some implementations, the forming the power pads may include forming the power pads on a side of the redistribution layer away from the first bonding layer. In some implementations, the power pads may be coupled to the redistribution layer.

In the example of the present disclosure, first power lines extending along the second direction are disposed in the first interconnection layer of the first peripheral area of the first semiconductor structure, and the first power lines are connected to the second power lines of the second semiconductor structure through the first connection structure. The second power line extends along a third direction intersecting with the second direction, so that the second power lines and the first power lines form a mesh structure, thus the power supply voltage can be distributed to different second power lines through the first power line. Since the construction of the power supply network utilizes the first peripheral area of the first semiconductor structure, the footprint of the power supply network on the second semiconductor structure can be reduced, and more space can be vacated in the second semiconductor structure to arrange signal lines, thus the wiring pitch can be increased, the signal wiring width can be increased to improve the signal quality, and increasing the wiring pitch for the high-speed signal lines can obtain a higher shielding effect.

Moreover, since the power supply network reduces its footprint on the second semiconductor structure, the line width of the power line, such as the second power line, in the second semiconductor structure can be increased, thereby reducing the resistance on the power line and reducing the voltage drop (IR drop). Moreover, the number of the first power lines in the first semiconductor structure can be increased, so that the first power lines output the power supply voltage to the second power line, and the voltage drop of the power supply network can also be reduced. In addition, since the first power line intersects with the second power line, and they are separated by the first bonding layer and the second bonding layer along the first direction, the crosstalk between them can be reduced, and the power supply network can be improved.

### BRIEF DESCRIPTION OF THE DRAWINGS

FIG. 1a is a first schematic diagram of an electronic device including a memory device according to an example of the present disclosure.

FIG. 1b is a second schematic diagram of an electronic device including a memory device according to an example of the present disclosure.

FIG. 2 is a schematic diagram of a main memory module according to an example of the present disclosure.

FIG. 3 is a schematic diagram of a solid state drive according to an example of the present disclosure.

FIG. 4 is a schematic diagram of a memory device including a peripheral circuit according to an example of the present disclosure.

FIG. 5 is a schematic diagram of a peripheral circuit according to an example of the present disclosure.

FIG. 6 is a structural schematic diagram of a memory device according to an example of the present disclosure.

FIG. 7 is a plan schematic diagram of a memory device according to an example of the present disclosure.

FIG. 8 is a schematic diagram of a bonding layer according to an example of the present disclosure.

FIG. 9 is a plan schematic diagram of another memory device according to an example of the present disclosure.

FIG. 10 is a first structural schematic diagram of another memory device according to an example of the present disclosure.

FIG. 11 is a plan schematic diagram of yet another memory device according to an example of the present disclosure.

FIG. 12 is a second structural schematic diagram of another memory device according to an example of the present disclosure.

FIG. 13 is a flowchart schematic diagram of a manufacturing method of a memory device according to an example of the present disclosure.

### DETAILED DESCRIPTION

Example implementations of the present disclosure will be described in more detail below with reference to the accompanying drawings. While example implementations of the present disclosure are shown in the accompanying drawings, it should be understood that the disclosure may be implemented in various forms and should not be limited by the example implementations set forth herein. Rather, these implementations are provided to enable a more thorough understanding of the present disclosure and to fully convey the scope of the disclosure to those skilled in the art.

In the following description, numerous specific details are given in order to provide a more thorough understanding of the present disclosure. It will be apparent to those skilled in the art, however, that the present disclosure may be practiced without one or more of these details. In other examples, to avoid confusion with the present disclosure, some technical features well-known in the art are not described; that is, not all features of the actual examples are described herein, and well-known functions and structures are not described in detail.

In the accompanying drawings, like reference numerals refer to like elements throughout.

It should be understood that spatial relation terms such as, “beneath”, “below”, “lower”, “under”, “over”, “upper”, etc. , may be used herein for ease of description to describe the relation of one element or feature and other elements or features shown in the figures. It should be appreciated that in addition to the orientations shown in the figures, it is intended that the spatial relation term also includes different orientations of the devices in use and operation. For example, if the devices in the figures are flipped, then an element or feature described as “below” or “under” or “beneath” the other elements will be oriented “on” other elements or features. Thus, the example terms “below” and “beneath” may include both upper and lower orientations. The devices may be additionally oriented (rotated 90 degrees or other orientations) and the spatial description terminology used herein is interpreted accordingly.

The terminology used herein is for the purpose of describing particular examples only and is not intended as a limitation of the present disclosure. As used herein, the singular forms “a,” “an,” and “the” are intended to include plural forms as well, unless the context clearly indicates otherwise. It should also be understood that at least one of the terms “consist of” or “include”, when used in this specification, determines the presence of at least one of stated features, integers, steps, operations, elements, or components, but do not preclude the presence or addition of at least one of one or more other features, integers, steps, operations, elements, components, or groups. As used herein, the term “at least one of” includes any and all combinations of related listed items.

The mainstream DRAM chip is prepared by using a single wafer, where a memory cell array and a peripheral circuit are formed on the same wafer, and routing is implemented between different modules through a metal layer (also referred to as an interconnection layer) to implement circuit functions. The metal layer is a conductive layer inside the integrated circuit chip for signal transmission and power distribution. Within the chip, each layer is responsible for a specific connection task by including a plurality of metal layers. In general, a low layer metal close to the wafer is configured for a short distance fine connection, for example, for local signal interconnection; while a middle layer metal farther away from the wafer is configured for longer distance signal transmission and some local power distribution, while a high layer metal farthest away from the wafer is configured, for example, for power distribution and long-distance signal transmission. Since the available metal layers are limited, only if the layout strategy of a signal line and a power line is continuously optimized, a balance can be obtained, to meet the requirements of higher performance, lower power consumption and higher integration.

With the rapid development of high-performance computing and artificial intelligence applications, demands for high-performance memory continue to climb. The present disclosure provides a DRAM chip of stacked architecture, where a memory cell array is manufactured on an array wafer, a peripheral circuit is manufactured independently on a peripheral circuit wafer, and control of the memory cell array by peripheral circuits is achieved by bonding contact connections. With the DRAM of stacked architecture, higher storage density, simpler process flow, and shorter process development cycle can be achieved.

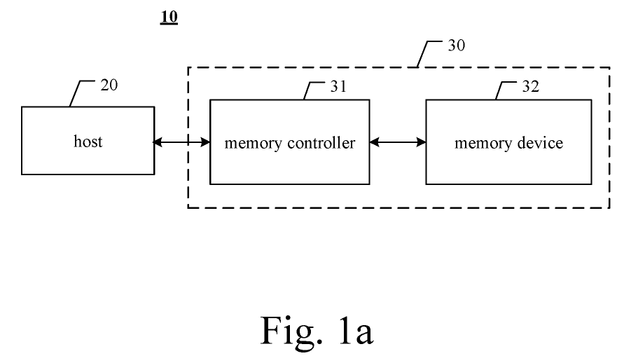

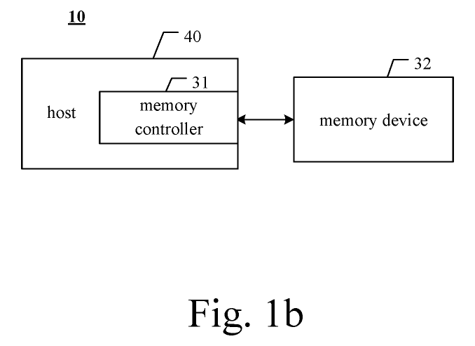

FIG. 1a and FIG. 1b are schematic diagrams of an electronic device including a memory device, according to an example of the present disclosure. The electronic device 10 includes, but is not limited to, a mobile phone, a desktop computer, a laptop computer, a tablet computer, a vehicle computer, a game console, a printer, a position device, a wearable electronic device, a smart sensor, a virtual reality (VR) device, an augmented reality (AR) device, or any other suitable electronic device having a memory therein.

In some examples, as shown in FIG. 1a, the electronic device 10 may include a host 20 and a memory system 30. The host 20 may be a processor (for example, a central processing unit (CPU), a graphics processing unit (GPU)), or a system on chip (SoC) (for example, an application processor (AP)) of the electronic device). The host 20 is configured to send data to or receive data from the memory system 30. Here, the memory system 30 may include a memory controller 31 and one or more memory devices 32. The memory controller 31 is coupled to the memory device 32 and the host 20 and is configured to control the memory device 32. The memory controller 31 may manage data stored in the memory device 32 and communicate with the host 20.

In some examples, the memory controller 31 may be packaged separately as a chip and be disposed on a motherboard of the electronic device 10, or the memory controller 31 is integrated in a north bridge chip of the computer motherboard.

In some other examples, as shown in FIG. 1b, the electronic device 10 may include a host 40 and one or more memory devices 32 coupled to the host 40. The memory controller 31 may be integrated in the host 40, for example, the memory controller 31 may be integrated into a CPU of a computer. When the memory controller 31 is a main memory controller, a delay of a main memory may be reduced by integrating it into the CPU.

The memory controller 31 may be configured to control operations of the memory device 32, such as read, write, and refresh operations. The memory controller 31 may send a command CMD and an address Add to the memory device 32. The command CMD may be a signal indicating the memory device 32 to write or read data by accessing a row of the memory cell array corresponding to the address Add. The address Add includes a memory bank address, a row address, and a column address to be accessed in the memory cell array. A plurality of independent channels (CH) may be configured for data transmission between the memory controller 31 and the memory device 32, and each channel may configure independent command interfaces, address interfaces, and data interfaces between the memory controller 31 and the memory device 32, and data access between the channels does not affect each other. In some implementations, the memory controller 31 is also configured to process error correction codes (ECC) regarding data read from or written to the memory device 32. The memory controller 31 may also perform any other suitable function, such as formatting the memory device 32.

In some examples, the memory device 32 may include, but is not limited to, a dynamic random access memory (DRAM), a synchronous DRAM (SDRAM), a double data rate SDRAM (DDR SDRAM), a DDR3 SDRAM, a DDR4 SDRAM, a DD5 SDRAM, a DD6 SDRAM, a high bandwidth memory (HBM), or the like. In the following description, as an example, the memory device 32 is illustrated as the DRAM 33.

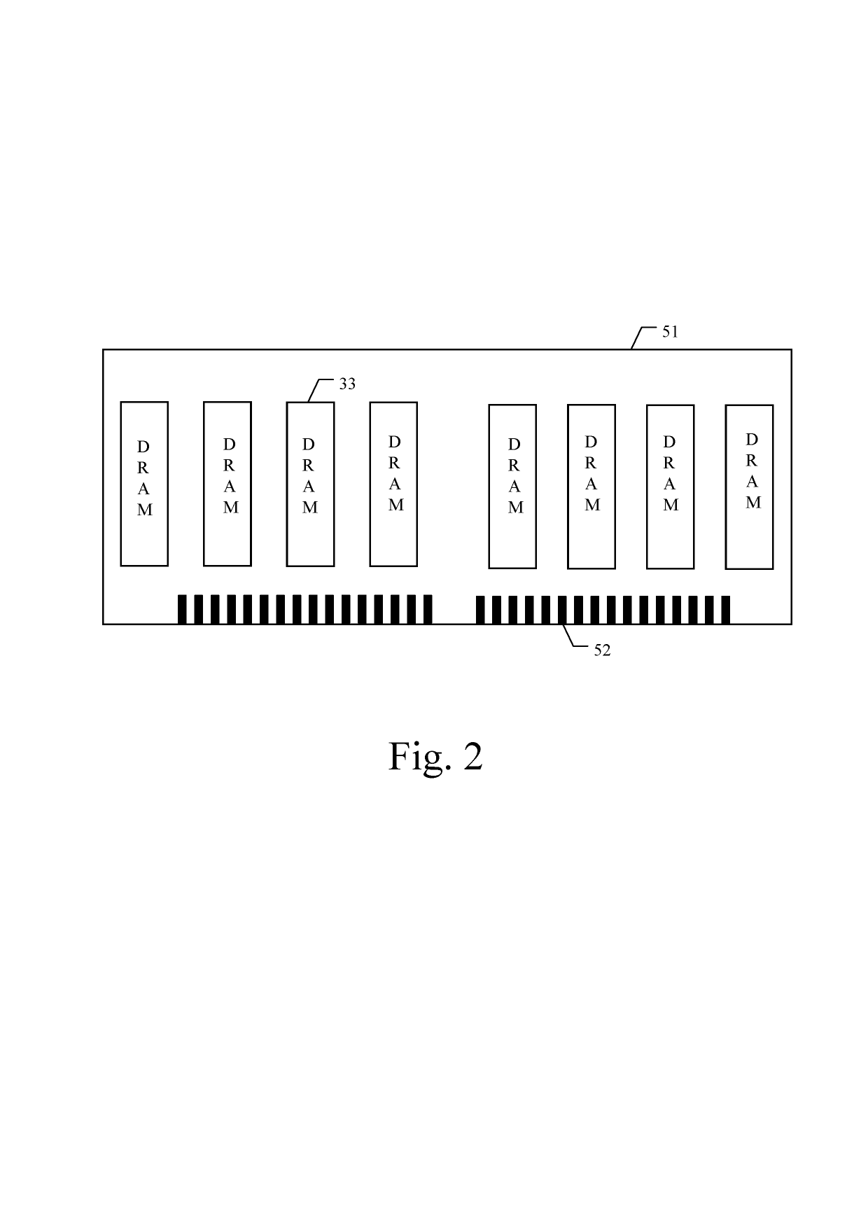

A plurality of DRAMs 33 may be grouped together to form the main memory module 51 shown in FIG. 2. The main memory module 51 may also include a main memory module connector 52 (e.g., a gold finger) coupling DRAM 33 with memory controller 31 integrated in a north bridge chip or processor. The main memory module 51 can be easily attached or mounted to or dismounted from the electronic device by the golden finger.

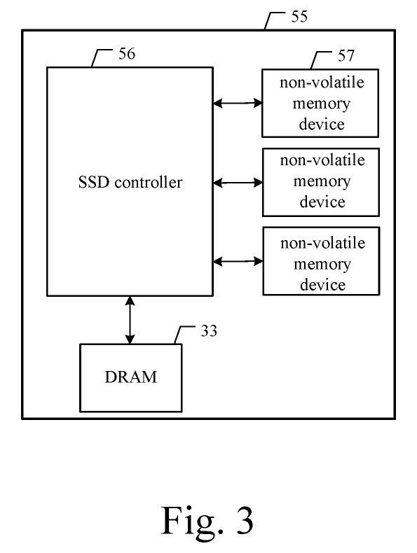

The DRAM 33 may also be integrated into a solid state drive (SSD) as a buffer memory. As shown in FIG. 3, the solid state drive 55 may include an SSD controller 56, a DRAM 33, and a non-volatile memory device 57, where the non-volatile memory device 57 serves as a storage medium of the solid state drive 55. The SSD controller 56 may provide a physical connection between a host (e.g., the host 20 in FIG. 1a) and the solid state drive 55. That is, the SSD controller 56 may provide an interface between the host and the solid state drive 55 according to the bus format of the host. The SSD controller 56 may decode instructions provided from the host. The SSD controller 56 may access the non-volatile memory device 57 based on the result of the decoding. The DRAM 33 may temporarily store write data provided from the host, or data read from the non-volatile memory device 57. When the host issues a read request, if the data present in the non-volatile memory device 57 is cached, the DRAM 33 may support caching functionality for providing cached data directly to the host. The data transfer rate through the bus format of the host (e.g., SATA or SAS) is much higher than the data transfer rate of the memory channel of the solid state drive 55. That is, performance degradation due to speed differences may be minimized by providing a high capacity DRAM 33 when the interface speed of the host is significantly high. In addition, the DRAM 33 may store an address mapping table of the non-volatile memory device 57. The non-volatile memory device 57 includes, but is not limited to, a NAND memory.

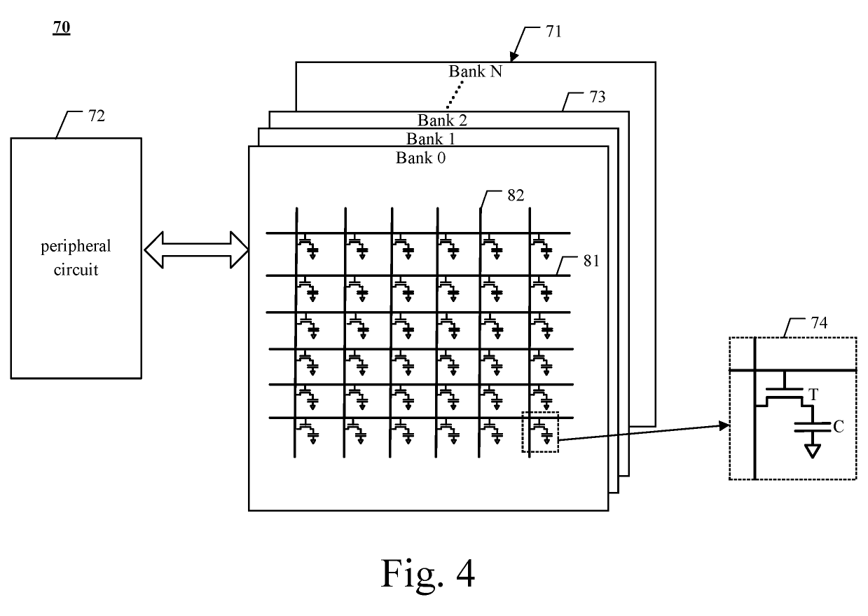

FIG. 4 is a schematic diagram of a memory device including a peripheral circuit according to an example of the present disclosure. The memory device 70 may be the memory device 32 in FIG. 1a to FIG. 1b, or the memory device 70 may be the DRAM 33 in FIG. 2 and FIG. 3. As shown in FIG. 4, the memory device 70 includes a memory cell array 71 and a peripheral circuit 72. Here, the memory cell array 71 may be a DRAM memory cell array. The memory cell array 71 may be divided into a plurality of memory banks 73, and the number of the memory banks 73 may be 8, 16, 32, 64, etc. In some examples, the memory banks 73 may also be organized into memory bank groups, each memory bank group including a plurality of memory banks 73. Each memory bank 73 may be activated individually, performing pre-charge, read and write operations, and the like.

In some examples, the memory bank 73 may include a plurality of memory blocks, and the memory block may include a plurality of memory cell rows and a plurality of memory cell columns. The memory cells 74 in the memory cell row are coupled to the same word line 81, which selects which of the plurality of memory cell rows is activated to perform a read or write operation. The memory cell 74 in the memory cell column is coupled to the same bit line 82; that is, the bit line 82 is connected to a first source/drain of the memory cell 74 located in the same column. The bit line 82 may select one memory cell column to be activated, or the bit line 82 may also select a plurality of memory cell columns to be activated in burst mode.

Each memory cell 74 may be a 1T1C cell composed of one transistor T and one capacitor C. The capacitor C stores one bit of data in the form of charge or electrons, where, in one example, data “1” may represent that more charge is stored in the capacitor C and data “0” may represent that less charge is stored in the capacitor C. The transistor T is configured to access and read and write data, the gate of the transistor T is connected to the word line 81, the first source/drain is connected to the bit line 82, and a second source/drain is connected to the capacitor C. The electrical signal applied on the word line 81 can control the switching-on or switching-off of the transistor T; and when the transistor T is switched on, the capacitor C communicates with the bit line 82, so that electrons can enter the capacitor through the bit line 82 to write the data “1”, or discharge the capacitor through the bit line 82 to write the data “0”. When transistor T is switched off, the capacitor C is isolated from the bit line 82, thereby preserving previously written data or charge. Further, the stored data in the capacitor C may also be read by measuring the amount of charge. Since the transistor T in the DRAM memory cell is very small, electrons within the capacitor C will be slowly leaked, thus over time the capacitor C needs to be refreshed in order to charge for the leaked electrons.

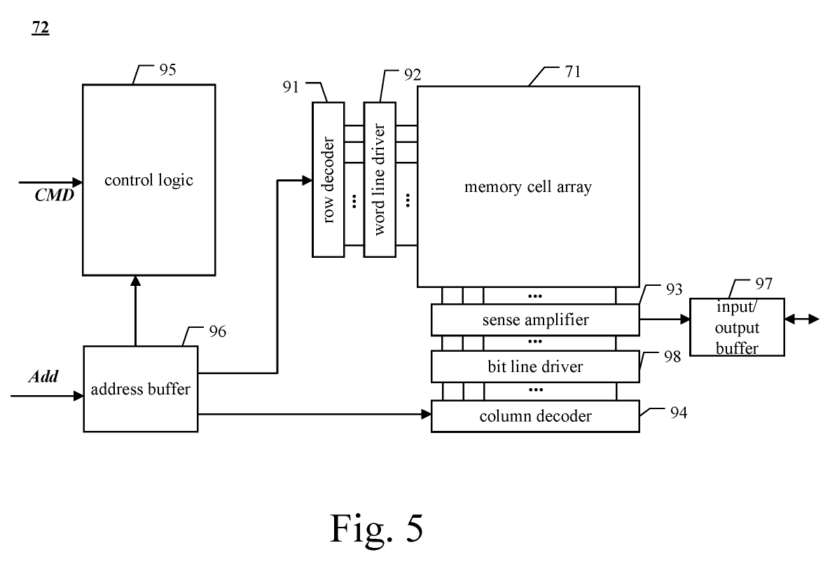

Still referring to FIG. 4, the peripheral circuit 72 may be coupled to the memory cell array 71 by the bit line 82 and the word line 81 and may include any suitable analog, digital, and mixed signal circuit configured to apply at least one of a voltage signal or a current signal to and sense at least one of the voltage signal or the current signal from the memory cells via the bit line and the word line to enable write and read operations of the memory cell array. The peripheral circuit 72 may include various types of peripheral circuits formed using metal-oxide-semiconductor (MOS) technology. FIG. 5 is a schematic diagram of a peripheral circuit 72 according to an example of the present disclosure, and the peripheral circuit 72 may include: a row decoder 91, a word line driver 92, a sense amplifier 93, a column decoder 94, a bit line driver 98, a control logic 95, an address buffer 96, a data input/output buffer 97, and the like. In an example, the control circuit corresponding to each memory bank 73 may include, but is not limited to, a row decoder 91, a word line driver 92, a sense amplifier 93, and a column decoder 94; that is, different memory banks 73 do not share these control circuits. In some examples, control circuit corresponding to all memory banks may include a control logic 95, an address buffer 96, a data input/output buffer 97, and the like. It should be understood that, in some examples, other peripheral circuits not shown in FIG. 5, such as a refresh control circuit, a memory bank control circuit, and the like, may also be included.

The row decoder 91 may be coupled to the address buffer 96, configured to receive the row address sent by the address buffer 96, decode the uniquely selected word line from the row address, and may connect the selected word line to the word line driver 92 configured to provide the control voltage. In some examples, the row decoder 91 may be coupled to a refresh control circuit and configured to receive the row address to be refreshed sent by the refresh control circuit.

The word line driver 92 is connected to the word lines, and the word line driver 92 may be configured to generate different control voltages to drive the word lines 81. In an example, the word line driver 92 may be configured to provide a control switching-on voltage to the selected word line according to a row select signal output by the row decoder, to turn on a transistor of the memory cell coupled with the selected word line.

The column decoder 94 may be configured to decode a uniquely selected bit line from the column address or a plurality of selected bit lines from the column address in a burst mode. The column decoder 94 may be further configured to generate a column selection signal according to the column address, where the column selection signal is configured to transmit the stored data of the sense amplifier 93 corresponding to the selected bit line to the data line, and to transmit it to the data input/output buffer 97 via the data line.

The bit line driver 98 is connected to a bit line, and the bit line driver 98 may be configured to convert the data signal into a voltage signal suitable for the bit line and drive it to the bit line 82. In an example, the bit line driver 98 may be configured to apply a high voltage or a low voltage to the bit line according to the data signal.

The sense amplifier 93 is connected to the bit line 82, and the sense amplifier 240 may sense a slight voltage fluctuation on the bit line 82, amplify, in a read operation, a small voltage swing of the bit line 82 to a logic level, that is, restore the stored value of the capacitor in the memory cell 74 according to the voltage fluctuation of the bit line.

The address buffer 96 may receive address information Add from the memory controller or the host. In one example, the address lines connected to the address buffer 96 are multiplexed, the address buffer 96 receives the row address information when the row strobe signal RAS is enabled, and receives the column address information when the column strobe signal CAS is enabled. The row address information includes an address of the memory bank group, the row address and an address of the memory bank, and the column address information includes the column address. The address buffer 96 transmits the addresses of the memory bank group and the memory bank to the memory bank group/memory bank controller, transmits the row address to the row decoder 91, and transmits the column address to the column decoder 94.

The control logic 95 may receive various commands CMD from the memory controller or the host and generate various control signals for controlling memory operations. The control logic 95 may include a command decoder configured to receive various commands CMDs and generate various control signals. The control logic 95 may by using control signals, read data from or write data to the memory cell array 71, or perform other operations. In an example, the control logic 95 may receive an activate command ACT and a read command READ to read data from the memory cell. The data input/output buffer 97 may receive data from or transmit data to the host or the memory controller.

As described above, the DRAM chip of the stacked architecture may achieve a higher storage density, a simpler process flow, and a shorter process development cycle to meet the needs in the field of high-performance computing, artificial intelligence, and the like. The DRAM chip of the stacked structure is formed by combining an array wafer and a peripheral circuit wafer, and the power supply network design of the DRAM chip can be different from the mainstream DRAM chip prepared by a single wafer. The design scheme of the power supply network in the DRAM chip of the stacked structure according to the example of the present application can make the power line in the power supply network have a small voltage drop, improve the performance of the power supply network, and provide more wiring space for the signal line.

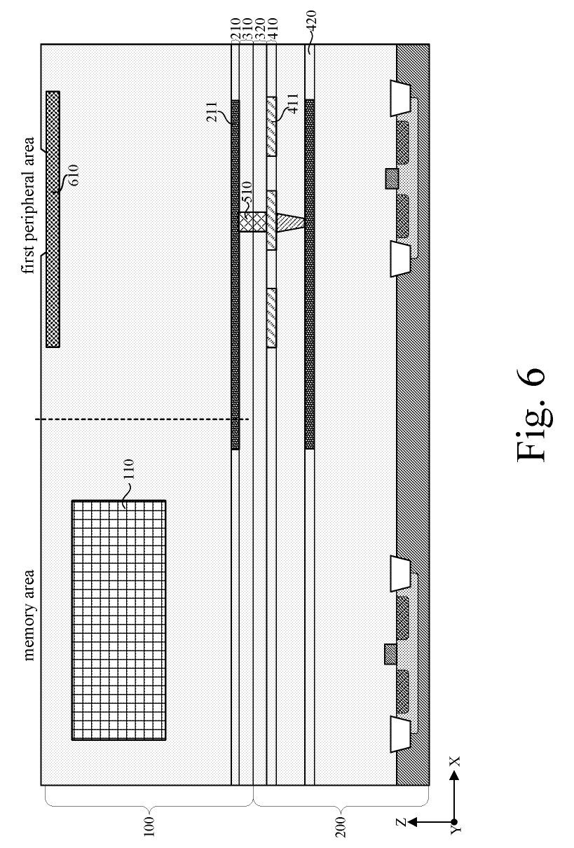

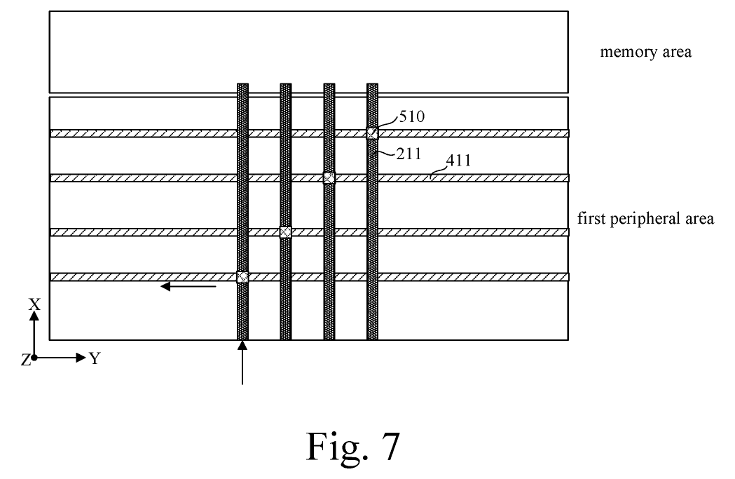

FIG. 6 is a structural schematic diagram of a memory device according to an example of the present disclosure, and FIG. 7 is a plan schematic diagram of a memory device. As shown in FIG. 6 and FIG. 7, the memory device includes a first semiconductor structure 100, a second semiconductor structure 200 and a plurality of first connection structures 510. The first semiconductor structure 100 includes a memory cell array 110, a first interconnection layer 210 and a first bonding layer 310 arranged along a first direction. The first interconnection layer 210 is in contact with the first bonding layer 310. The first direction is perpendicular to a plane where the first interconnection layer 210 is located; where the memory cell array 110 is located in a memory area of the first semiconductor structure 100, the first interconnection layer 210 includes a plurality of first power lines 211 extending along a second direction, the first power line 211 is at least partially located in a first peripheral area of the first semiconductor structure 100, and the memory area and the first peripheral area are arranged along the second direction.

The second semiconductor structure 200 includes a second bonding layer 320 and a second interconnection layer 410 sequentially stacked along the first direction and in contact with each other, where the second bonding layer 320 is further in contact with the first bonding layer 310, the second interconnection layer 410 includes a plurality of second power lines 411 extending along a third direction, and the third direction intersects with the second direction.

The first connection structure 510 extends through the first bonding layer 310 and the second bonding layer 320 along the first direction, each second power line 411 is coupled to the at least one first power line 211 through at least one first connection structure 510, and two ends of the first connection structure 510 are respectively connected to the first power line 211 and the second power line 411.

In the example of the present disclosure, the first direction is perpendicular to a plane where the first interconnection layer is located, and both the second direction and the third direction are parallel to the plane where the first interconnection layer is located and the second direction intersects with the third direction. For example, the second direction may be perpendicular to the third direction. The present disclosure is illustrated by taking the second direction being perpendicular to the third direction as an example, and in an example, taking the first direction being the Z direction, the second direction being the X direction, and the third direction being the Y direction as an example.

Since the first semiconductor structure 100 has the memory cell array 110 formed therein, the first semiconductor structure 100 may be referred to as an array wafer. For example, the memory cell array 110 includes a dynamic random access memory cell array, which may be, for example, the memory cell array 71 as shown in FIG. 4 and FIG. 5 described above. The second semiconductor structure 200 has a peripheral circuit formed therein, and the peripheral circuit is configured to control the memory cell array 110 to perform various operations. The peripheral circuit may be the peripheral circuit 72 shown in FIG. 4 and FIG. 5 described above. The second semiconductor structure 200 may also be referred to as a peripheral circuit wafer.

As shown in FIG. 6, in the first semiconductor structure 100, the memory cell array 110, the first interconnection layer 210 and the first bonding layer 310 are sequentially disposed along the first direction (Z direction). The first semiconductor structure 100 includes a memory area and a first peripheral area arranged along a second direction (X direction), where the memory cell array 110 is located in the memory area, and the first interconnection layer 210 is disposed in the memory area and the first peripheral area. As shown in FIG. 6 and FIG. 7, the first interconnection layer 210 includes a plurality of first power lines 211 extending along the second direction. For example, the plurality of first power lines 211 may be divided into a plurality of groups, each group includes at least two first power lines 211, and the first power lines 211 in each group may be disposed side by side along the third direction (Y direction). The plurality of groups of first power lines 211 may be arranged along at least one of the second direction or the third direction, and only one first power line 211 of one group of first power lines is shown in FIG. 6.

In the second semiconductor structure 200, the second interconnection layer 410 includes a plurality of second power lines 411 extending along the third direction (Y direction). The second power line 411 intersects with the first power line 211. For example, as shown in FIG. 6 and FIG. 7, the second power line 411 and the first power line 211 are perpendicular to each other. The plurality of second power lines 411 may be arranged side by side along the second direction (X direction). Each second power line 411 is connected to at least one first power line 211 through at least one first connection structure 510, which means that the second power line 411 may be connected to one first power line 211 through one or more first connection structures 510, and the second power line 411 may also be connected to the plurality of first power lines 211 through a plurality of first connection structures 510. When the power supply voltage is provided to the second power line 411 by using the plurality of first power lines 211, it is advantageous for reducing the voltage drop of the first power line 211.

As shown in FIG. 7, in a plan diagram of the memory device parallel to the first interconnection layer 210, the plurality of first power lines 211 extend along the second direction (X direction), the plurality of second power lines 411 extend along the third direction (Y direction), and each second power line 411 intersects with at least one first power line 211 to form a mesh structure. The first power line 211 and the second power line 411 are both wiring in the power supply network within the memory device, and the power supply network performs power distribution, supplies power supply voltage to each control circuit in the memory device, and ensures normal operation of the circuit. For example, the power line is thicker than the signal line and the data line, which can reduce the resistance and the voltage drop. The power supply voltage may be a positive power supply voltage, such as VDD, VDDQ, VPP, VCC, etc., and the power supply voltage may also be a negative power supply voltage or a ground voltage, for example, VSS.

An intersection of the second power line 411 and at least one first power line 211 is provided with the first connection structure 510. As shown in FIG. 6, the first connection structure 510 penetrates through the first bonding layer 310 and the second bonding layer 320, and one end of the first connection structure 510 is in contact with the first power line 211, and the other end is in contact with the second power line 411. The first power line 211 may perform power supply voltage transmission with the second power line 411 through the first connection structure 510. For example, as shown by the arrow in FIG. 7, the first power line 211 may transmit the power supply current to the second power line 411 through the first connection structure 510. It should be noted that, in FIG. 7, the first connection structure 510 is actually located between the first power line 211 and the second power line 411, and is displayed on the first power line 211 here in order to clearly describe the position of the first connection structure 510.

In the example of the present disclosure, a plurality of first power lines 211 extending along the second direction are disposed in the first interconnection layer 210 of the first peripheral area of the first semiconductor structure 100, and the plurality of first power lines 211 are connected to the plurality of second power lines 411 of the second semiconductor structure 200 through the first connection structure 510. The second power line 411 extends along the third direction intersecting with the second direction, so that the plurality of second power lines 411 and the plurality of first power lines 211 form a mesh structure, so that the power supply voltage can be distributed to different second power lines 411 through the first power line 211. Since the construction of the power supply network utilizes the first peripheral area of the first semiconductor structure 100, the footprint of the power supply network on the second semiconductor structure 200 can be reduced, and more space can be vacated in the second semiconductor structure 200 to arrange signal lines, so that the wiring pitch can be increased, the signal line wiring width can be increased to improve the signal quality, and the increase of the wiring pitch for the high-speed signal lines can obtain a higher shielding effect.

Moreover, since the power supply network reduces its footprint on the second semiconductor structure 200, the line width of the power line, such as the second power line, in the second semiconductor structure 200 can be increased, thereby reducing the resistance on the power line and reducing the voltage drop (IR drop). Moreover, by increasing the number of the first power lines 211 in the first semiconductor structure 100, making the plurality of first power lines 211 output the power supply voltage to the second power line 411, the voltage drop of the power supply network can also be reduced. In addition, since the first power line 211 intersects with the second power line 411, and are separated by the first bonding layer 310 and the second bonding layer 320 therebetween along the first direction, the crosstalk between each other can be reduced, and the power supply network can be improved.

In some examples, as shown in FIG. 6, a side of the first semiconductor structure 100 away from the first bonding layer 310 is provided with a plurality of power pads 610, and the plurality of power pads 610 are coupled to the plurality of first power lines 211.

For example, the plurality of power pads 610 are coupled to the plurality of first power lines 211 and may include one or more of the following cases: each power pad 610 is coupled to one first power line 211; each power pad 610 is coupled to a plurality of first power lines 211; and a plurality of power pads 610 are coupled to one first power line.

Power pad 610 is a pad of the pads of the memory device for receiving a power supply voltage. The power pad 610 may be connected to a power supply circuit external to the memory device for receiving the power supply voltage provided by the external power supply circuit. For example, the plurality of power pads 610 may include at least one of a VDD pad, a VDDQ pad, a VPP pad, a VCC pad, a VSS pad, or the like of the memory device.

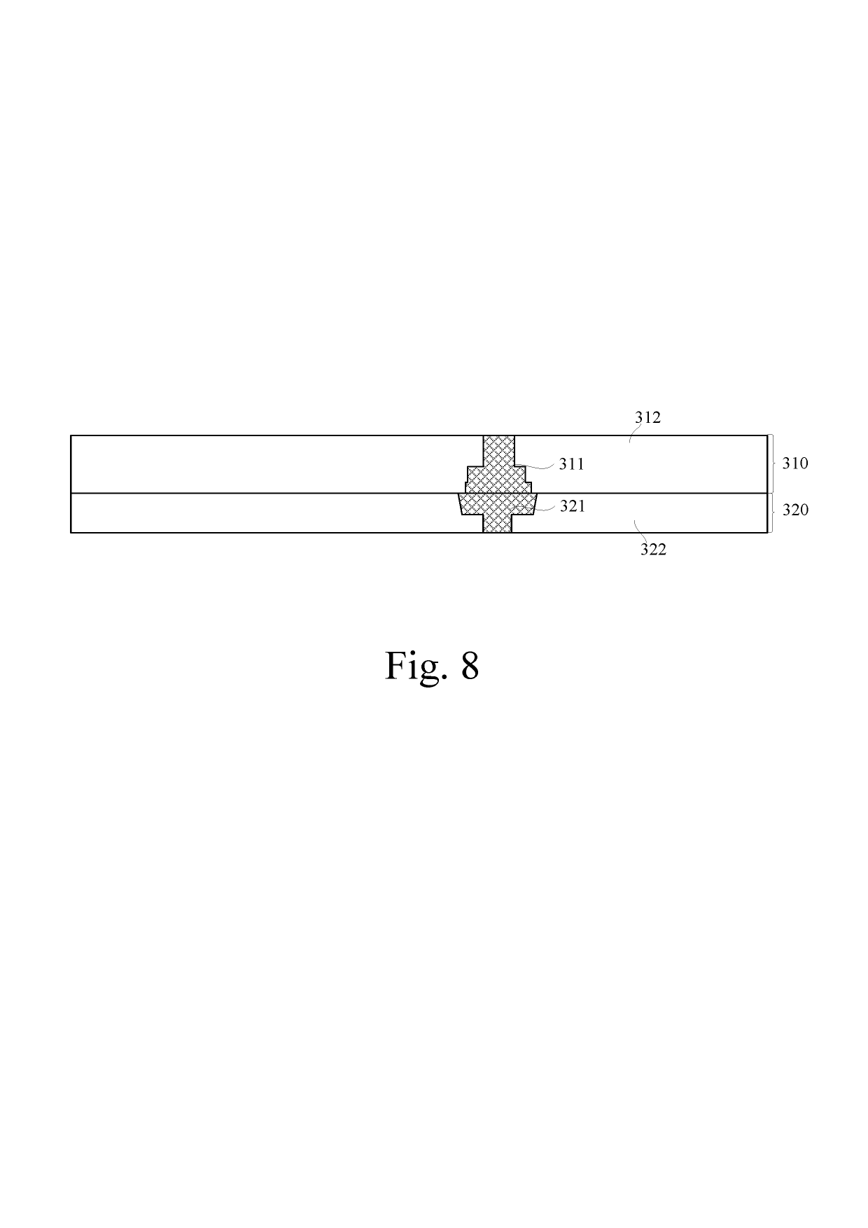

In some examples, as shown in FIG. 8, each first connection structure 510 includes a first bonding contact 311 located in the first bonding layer 310, and a second bonding contact 321 located in the second bonding layer 320, and the first bonding contact 311 and the second bonding contact 321 are bonded, where the first bonding contact 311 is in contact with the first power line 211, and the second bonding contact 321 is in contact with the second power line 411.

In the present example, the first semiconductor structure 100 and the second semiconductor structure 200 are bonded in a hybrid bonding manner. The first bonding layer 310 includes a first dielectric layer 312 and a first bonding contact 311 located in the first dielectric layer 312 that insulate the first bonding contacts 311 from each other. The second bonding layer 320 includes a second dielectric layer 322 and a second bonding contact 321 located in the second dielectric layer 322. When the first bonding layer 310 and the second bonding layer 320 are bonded, the first bonding contact 311 and the second bonding contact 321 are in contact and bonded with each other, and the first dielectric layer 312 and the second dielectric layer 322 are bonded with each other. The first power line 211 and the second power line 411 transmit the power supply voltage through the first bonding contact 311 and the second bonding contact 321.

In some examples, as shown in FIG. 6 and FIG. 7, most of the first power line 211 is located in the first peripheral area. That most of the first power line 211 is located in the first peripheral area means that more than half of the first power line 211 is in the first peripheral area.

The first semiconductor structure 100 is mainly configured to form the memory cell array, with fewer wiring in the first peripheral area. According to the example of the present disclosure, several first power lines 211 extending along the second direction in the power supply network are formed by utilizing the first peripheral area, so that the power grid can be improved, and the utilization rate of the first peripheral area can be improved. That most of the first power line extends in the first peripheral area may reduce the footprint of the first power line in the memory area and also reduce the influence on the signal line and the data line in the memory area.

In an example of the present disclosure, the number of the memory areas may be one or more, and the memory cell array 110 is located in all memory areas. In some examples, the number of the memory areas is two. In an example, the first semiconductor structure includes a first memory area and a second memory area disposed at an interval along a second direction (X direction), and the first peripheral area is located between the first memory area and the second memory area; where the first power line 211 penetrates through the first peripheral area along the second direction.

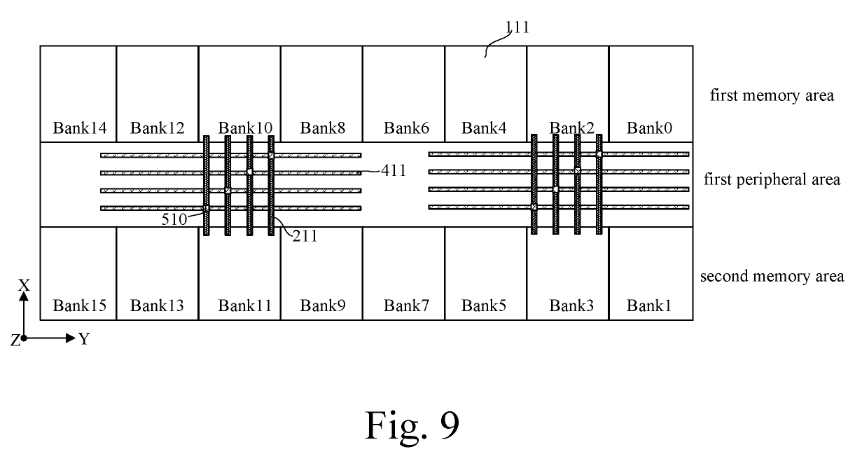

FIG. 9 is a schematic diagram of still another memory device according to an example of the present disclosure. As shown in FIG. 9, the first memory area and the second memory area are symmetrically disposed on two sides of the first peripheral area along the second direction (X direction). The memory cell array 110 is divided into a plurality of memory banks 111, which may be, for example, the memory banks 73 in FIG. 4. For example, a half number of the memory banks Bank1, Bank3, Bank5, Bank7, Bank9, Bank11, Bank13, and Bank15 are disposed in the first memory area, and another half number of the memory banks Bank0, Bank2, Bank4, Bank6, Bank8, Bank10, Bank12, and Bank14 are disposed in the second memory area. Each memory bank in the first memory area is disposed opposite, along the second direction, to one memory bank in the second memory area, for example, the memory bank Bank0 and the memory bank Bank1 are disposed opposite to each other.

The first peripheral area is located between the first memory area and the second memory area, and the first power line 211 extends through the first peripheral area along the second direction. For example, as shown in FIG. 9, two ends of the first power line 211 may respectively extend to the first memory area and the second memory area.

In some examples, the first semiconductor structure 100 may include a plurality of interconnection layers; in the first peripheral area, extension directions of power lines in adjacent two interconnection layers intersect. For example, power lines of two adjacent interconnection layers are perpendicular to each other. In this way, the intersection of the power lines in two adjacent interconnection layers can reduce the crosstalk between the power lines, which helps to ensure the integrity of the power supply.

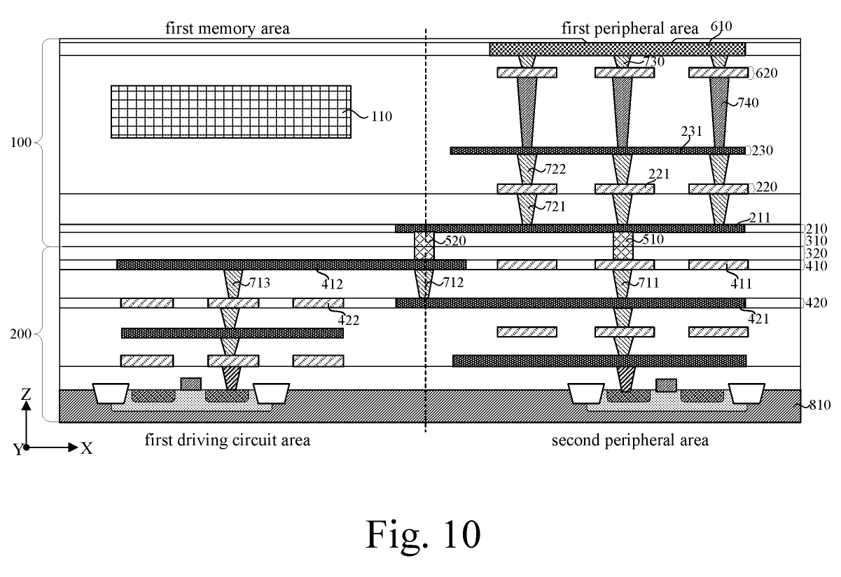

The first interconnection layer 210 is an interconnection layer of the plurality of interconnection layers of the first semiconductor structure 100, which is closest to the first bonding layer 310. In addition, as shown in FIG. 10, the first semiconductor structure 100 further includes a third interconnection layer 220 adjacent to the first interconnection layer, and the third interconnection layer 220 is located on a side of the first interconnection layer 210 away from the first bonding layer 310. The third interconnection layer 220 includes a plurality of third power lines 221 extending along the third direction (Y direction), which located in the first peripheral area, and the plurality of third power lines 221 are coupled to the plurality of first power lines 211. For example, the third power line 221 is perpendicular to the first power line 211.

For example, the third power line 221 is coupled to the first power line 211 through the fourth interconnection access 721.

For example, the number of the third power lines 221 is less than the number of the first power lines 211. One third power line may be coupled to a plurality of first power lines. It may be understood that the third power line 221 functions to transmit the power supply voltage to the first interconnection layer, and the first power line in the first interconnection layer may function to distribute the power supply, and several first power lines may distribute the power supply voltage to different functional circuits.

For example, the number of the third power lines 221 is less than the number of the second power lines 411. As shown in FIG. 10, the third power line 221 and the second power line 411 have the same extension direction, but the number of the third power lines 221 is less than the number of the second power lines 411. The second power line 411 may transmit the power supply voltage to different control circuits along the third direction (Y direction).

In some examples, the first semiconductor structure 100 further includes: a redistribution layer (RDL) 620 located between the plurality of power pads 610 and the memory cell array 110, the redistribution layer 620 is disposed in the memory area and the first peripheral area, and coupled to a plurality of power pads 610 and a plurality of third power lines 221.

As shown in FIG. 10, the redistribution layer 620 is located between the pad of the memory device and the memory cell array 110 and extends in the memory area and the first peripheral area. The redistribution layer 620 is configured to redistribute the interface (I/O) locations of the memory device to accommodate different package requirements and improve the flexibility of electrical connections. The power pads 610 may be located in the memory area or in the first peripheral area, or may be located in other areas outside the memory area and the first peripheral area. For example, in some examples, the first semiconductor structure 100 further includes an edge peripheral area located on a side of the memory area and the first peripheral area along the third direction (Y direction), and the power pads 610 may be located in the memory area, the first peripheral area, or the edge peripheral area. The power pads 610 may be coupled, through the redistribution layer 620, to the power line in the interconnection layer closest to the redistribution layer 620 in the first peripheral area.

For example, as shown in FIG. 10, the power pads 610 may be connected to the redistribution layer 620 through one or more conductive accesses 730. The conductive access 730 may be, for example, a conductive via (Via).

For example, the redistribution layer 620 may be coupled to a power line in the interconnection layer closest to the redistribution layer 620 in the first peripheral area through the conductive connection structure 740. Referring to FIG. 10, the plurality of interconnection layers of the first semiconductor structure 100 are all located on a side of the memory cell array 110 close to the first bonding layer 310, while the redistribution layer 620 is located on the other side of the memory cell array 110, the conductive connection structure 740 may penetrate through the substrate of the first semiconductor structure 100, and one end of the conductive connection structure 740 is connected to the redistribution layer 620, and the other end of the conductive connection structure 740 is connected to the interconnection layer closest to the redistribution layer 620. For example, the conductive connection structure 740 is a through silicon via (TSV).

In some examples, the first semiconductor structure 100 further includes a fifth interconnection layer 230 located on a side of the third interconnection layer 220 away from the first interconnection layer 210. The fifth interconnection layer 230 includes a plurality of seventh power lines 231 extending along the second direction (X direction), and the plurality of seventh power lines 231 are coupled to the plurality of third power lines 221. For example, the seventh power line 231 and the third power line 221 are perpendicular to each other, and the seventh power line 231 is parallel to the first power line 211. For example, the number of the seventh power lines 231 is less than the number of the first power lines 211. The seventh power line 231 only functions to transmit the power supply voltage.

For example, the seventh power line 231 may be coupled to the third power line 221 through the fifth interconnection access 722.

In some examples, as shown in FIG. 10, the first semiconductor structure includes only three interconnection layers, e.g., a first interconnection layer 210, a third interconnection layer 220, and a fifth interconnection layer 230, respectively. The fifth interconnection layer 230 is an interconnection layer closest to the redistribution layer 620, and the redistribution layer 620 is connected to the seventh power line 231 in the fifth interconnection layer 230 through the conductive connection structure 740.

In some examples, the second semiconductor structure 200 includes a second peripheral area and a driving circuit area disposed along the second direction (X direction), the second peripheral area corresponds to the first peripheral area, and the driving circuit area corresponds to the memory area; where the second power line 411 is located in the second peripheral area.

Herein, that the second peripheral area corresponds to the first peripheral area means that the second peripheral area is disposed opposite to at least a partial area of the first peripheral area. In other words, in a plan diagram of the memory device parallel to the first interconnection layer, the second peripheral area overlaps at least a partial area of the first peripheral area.

That the memory area corresponds to the driving circuit area means that the memory area is disposed opposite to at least partial areas of the driving circuit area. In a plan diagram of the memory device parallel to the first interconnection layer, the driving circuit area overlaps at least a partial area of the memory area.

In the present example, as shown in FIG. 9, as an example for description, a first peripheral area and a second peripheral area are completely opposite to each other but overlap in the plan diagram, and the memory area and the driving circuit area are completely opposite to each other but overlap in the plan diagram.

As shown in FIG. 10, the second power line 411 is located in the second peripheral area. Different second power lines 411 are configured to transmit the power supply voltage to the corresponding control circuit along the third direction (Y direction).

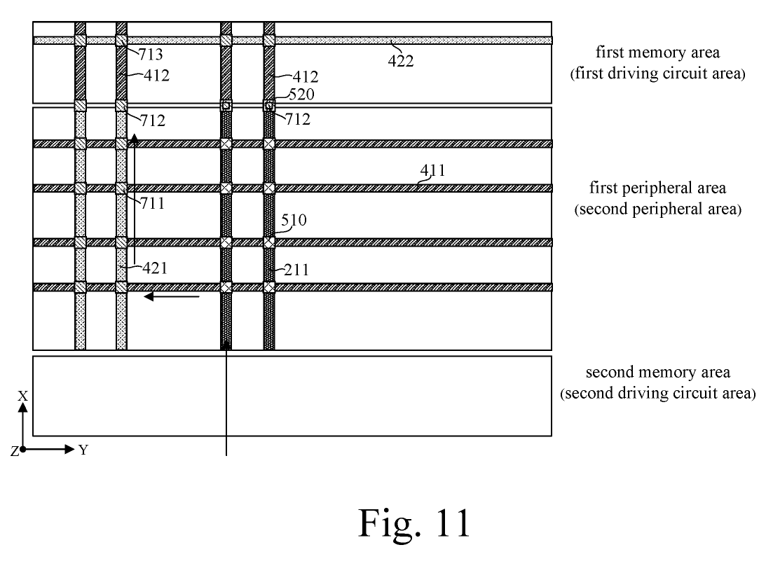

FIG. 11 is a plan schematic diagram of yet another memory device according to an example of the present disclosure. It should be noted that, regarding the actual positions of the first connection structure 510, the second connection structure 520, the first interconnection access 711, the second interconnection access 712, and the third interconnection access 713 in FIG. 11, FIG. 10 can be referred, and FIG. 11 shows that they are on the first power line 211 in order to clearly describe their positions. It should also be noted that the second power line 411, the fourth power line 412, the fifth power line 421, and the sixth power line 422 are filled in different manners as shown in FIG. 10 only for illustration of the positions of the second power line 411, the fourth power line 412, the fifth power line 421 and the sixth power line 422 in the plan diagram; and the second power line 411 and the fourth power line 412 adopt dark gray background filling to indicate that they are both in the second interconnection layer, and the fifth power line 421 and the sixth power line 422 adopt the light gray background filling to indicate that they are both in the fourth interconnection layer.

In some examples, referring to FIG. 10 and FIG. 11, the second interconnection layer 410 further includes a plurality of fourth power lines 412 extending along the second direction (X direction), the fourth power line 412 is at least partially located in the driving circuit area (e.g., the first driving circuit area); the fourth power line 412 has a first end and a second end disposed opposite to each other in the second direction, the first end is close to the second peripheral area, where the first end is coupled to the first power line 211 through the second connection structure 520, and the second connection structure 520 extends through the first bonding layer 310 and the second bonding layer 320 along the first direction and is disposed at an interval with the first connection structure 510.

As described above, some of the control circuits in the peripheral circuit are used individually by each memory bank, e.g., the row decoder 91, the word line driver 92, the sense amplifier 93, the column decoder 94 in FIG. 4. For example, the control circuits used individually by each memory bank 111 may be disposed in a substrate of the driving circuit area. To supply power to this part of control circuits, the fourth power line 412 may be disposed in the second interconnection layer 410.

At least most of the fourth power line 412 is located in the driving circuit area, which means that the fourth power line 412 may be completely located in the driving circuit area, or most of the fourth power line may be located in the driving circuit area but the line end may extend to the second peripheral area. Referring to FIG. 10 and FIG. 11, in this example, the first end of the fourth power line 412 extends to the second peripheral area, an end of the first power line 211 extends to the memory area (the first memory area in FIG. 11), and the first end of the fourth power line 412 is coupled to one end of the first power line 211 at the junction of the memory area and the second peripheral area through the second connection structure 520.

In another example, the fourth power line 412 may also be completely in the driving circuit area, only the end of the first power line 211 extends to the memory area, and the end of the first power line 211 and the first end of the fourth power line 412 are coupled through the second connection structure at the edge of the driving circuit area. In another example, only the first end of the fourth power line 412 extends to the second peripheral area, and the first power line 211 is completely in the first peripheral area and the first end of the fourth power line 412 is coupled to the end of the first power line 211 at the edge of the second peripheral area through the second connection structure 520.

The fourth power line 412 is coupled to one first power line 211 through the second connection structure 520. The second connection structure 520 includes a third bonding contact located in the first bonding layer 310 and a fourth bonding contact located in the second bonding layer 320, the third bonding contact and the fourth bonding contact are bonded, where the third bonding contact is in contact with the first power line 211, and the fourth bonding contact is in contact with the fourth power line 412.

In some examples, in each interconnection layer, a power line located in the driving circuit area intersects with an extension direction of the power line located in the second peripheral area. For example, the power line located in the driving circuit area is perpendicular to the power line located in the second peripheral area. As shown in FIG. 10 and FIG. 11, the fourth power line 412 and the second power line 411 both located in the second interconnection layer 410 are perpendicular to each other.

In some examples, the second semiconductor structure 200 includes a plurality of interconnection layers; in the second peripheral area, the extension directions of the power lines in adjacent interconnection layers intersect. For example, in the second peripheral area, power lines in adjacent interconnection layers are perpendicular to each other.

In some examples, as shown in FIG. 10 and FIG. 11, the second semiconductor structure 200 further includes a fourth interconnection layer 420 adjacent to the second interconnection layer 410, the fourth interconnection layer 420 is located on a side of the second interconnection layer 410 away from the second bonding layer 320, the fourth interconnection layer 420 includes a plurality of fifth power lines 421 extending along the second direction (X direction), the fifth power line 421 is at least partially located in the second peripheral area, and each fifth power line 421 may be coupled to at least one second power line 411 through the first interconnection access 711.

For example, the fifth power line 421 and the second power line 411 are perpendicular to each other. For example, the first interconnection access 711 may be a conductive via (Via).

As shown in FIG. 11, the first power line 211 can transmit the power supply current along the second direction (X direction) and distribute the power supply current to different second power lines 411, the second power line 411 can transmit the power supply current along the third direction (Y direction) and distribute the power supply current to different fifth power lines 421, and the fifth power line 421 is closer to the control circuit at the substrate of the second semiconductor structure to further transmit the power supply current to the control circuit.

In some examples, as shown in FIG. 10 and FIG. 11, the first end of the fourth power line 412 is coupled to the fifth power line 421 through the second interconnection access 712.

Referring to FIG. 10 and FIG. 11, in this example, the first end of the fourth power line 412 extends to the second peripheral area, the end of the fifth power line 421 extends to the driving circuit area (the first driving circuit area in FIG. 11), and the first end of the fourth power line 412 and the end of the fifth power line 421 are coupled through the second interconnection access 712 at the junction of the driving circuit area and the second peripheral area.

In another example, the fourth power line 412 may also be completely in the driving circuit area, only an end of the fifth power line 421 extends to the driving circuit area, and the end of the fifth power line 421 is coupled to the first end of the fourth power line 412 in the driving circuit area through the second interconnection access 712. In another example, only the first end of the fourth power line 412 extends to the second peripheral area, and the fifth power line 421 is completely in the second peripheral area, and the first end of the fourth power line 412 and the end of the fifth power line 421 are coupled at the second peripheral area through the second interconnection access 712.

For example, as shown in FIG. 10 and FIG. 11, the second interconnection structure 520 may be located over the second interconnection access 712. That is, the second interconnection structure 520 and the second interconnection access 712 may overlap in the plan diagram of the memory device.

The fifth power line 421 and the second power line 411 may transmit a power supply voltage therebetween, or the fifth power line 421 and the fourth power line 412 may transmit a power supply voltage therebetween. The fifth power line 421 enables the driving circuit area and the second peripheral area of two adjacent interconnection layers to transmit power directly to improve the flexibility of the power supply network.

In some examples, in the driving circuit area, extension directions of power lines in adjacent interconnection layers intersect. For example, in the driving circuit area, the power lines in the adjacent interconnection layers are perpendicular to each other. In this way, the crosstalk of the power lines in the adjacent interconnection layers can be reduced, and performance of the power supply network can be improved.

For example, as shown in FIG. 10 and FIG. 11, the fourth interconnection layer 420 further includes a plurality of sixth power lines 422 extending along the third direction (Y direction) that are located in the driving circuit area; and the sixth power line 422 is coupled to the fourth power line 412 through the third interconnection access 713. For example, the sixth power line 422 and the fourth power line 412 are perpendicular to each other.

The sixth power line 422 is closer to the control circuit in the substrate 810 of the second semiconductor structure, may receive the power supply current transmitted by the fourth power line 412 and further transmit the power supply current to the control circuit of the driving circuit area.

In some examples, the power lines of the driving circuit area and the power lines of the second peripheral area intersect (e.g., are perpendicular to each other) in the same interconnection layer of the second semiconductor structure. The power lines in the driving circuit areas of the adjacent interconnection layers intersect (e.g., are perpendicular to each other), and the power lines of the second peripheral areas of the adjacent interconnection layers intersect (e.g., are perpendicular to each other). In this way, the crosstalk between the power lines can be reduced, and the power supply network can be improved. Moreover, the first connection structure 510, the second connection structure 520, the first interconnection access 711, the second interconnection access 712 and the third interconnection access 713 realize the vertical (Z direction) transmission of the power supply voltage, also realize the transmission of the power supply voltage between the driving circuit area and the second peripheral area, and can provide the power supply voltage to the control circuit of the driving circuit area and the control circuit of the second peripheral area. The control circuit of the second peripheral area may include a control logic, an address buffer, a refresh control circuit, a memory bank control circuit, a data input/output buffer, and the like. The control logic, the address buffer, and the data input/output buffer may be the control logic 95, the address buffer 96, and the data input/output buffer 97 in FIG. 4.

It should be noted that FIG. 10 and FIG. 11 show only the fourth power line 412 and the sixth power line 422 in the first driving circuit area, and the fourth power line 412 and the sixth power line 422 may also be disposed in the second driving circuit area and the first driving circuit area. In addition, the power lines of the second driving circuit area and the first driving circuit area may be symmetrically disposed.

In some examples, the second semiconductor structure may include five interconnection layers, in addition to the second interconnection layer 410 and the fourth interconnection layer 420, further including three interconnection layers sequentially located below the fourth interconnection layer 420. The fourth interconnection layer 420 may be coupled to a plurality of control circuits in the substrate 810 through the other three interconnection layers.

In some examples, at least one of a sense amplifier, a word line driver, a row decoder and a column decoder is disposed in the substrate 810 of the second semiconductor structure, which is located in the driving circuit area and is coupled to the sixth power line 422. The sixth power line 422 provides a power supply voltage for these control circuits.

For example, a sense amplifier, a word line driver, a row decoder and a column decoder may be the row decoder 91, the word line driver 92, the sense amplifier 93, and the column decoder 94 as shown in FIG. 4.

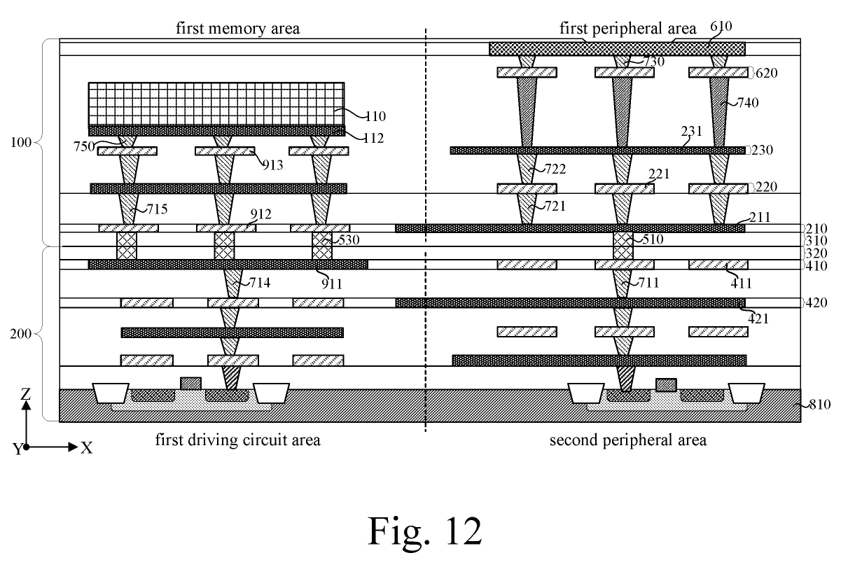

FIG. 12 is a second structural schematic diagram of another memory device according to an example of the present disclosure, which is a different cross-section perpendicular to the first interconnection layer of the memory device as shown in connection with FIG. 10. In some examples, as shown in FIG. 12, the second interconnection layer 410 further includes a plurality of signal lines 911 located in the driving circuit area (for example, the first driving circuit area), and each signal line 911 is coupled to one of the sense amplifier, the word line driver, the row decoder and the column decoder.

For example, the signal lines 911 may be connected to these control circuits through the fourth interconnection layer 420, the other interconnection layers under the fourth interconnection layer 420, and the interconnection accesses 714 between adjacent interconnection layers. The control circuit mainly includes a transistor located in the substrate 810, and a contact plug is disposed between the interconnection layer closest to the substrate and the source and the gate of the transistor in the substrate 810.

The first interconnection layer 210 further includes a plurality of lead-out structures 912 arranged in an array, which is located in the memory area (for example, the first memory area); each lead-out structure 912 is coupled to one bit line 112 or one word line of the memory cell array.

For example, the lead-out structure 912 may be coupled to the memory cell array 110 through the third interconnection layer 220, the fifth interconnection layer 230, and the interconnection access 715 between adjacent interconnection layers, for example, may be coupled to the bit lines, word lines of the memory cell array 110, and an electrode of the capacitor in the memory cell. For example, a through-silicon contact (TSC) 750 may be disposed between the fifth interconnection layer 230 and the memory cell array to enable coupling of the fifth interconnection layer 230 to at least one of the bit line, the word line, and the electrode of the capacitor.

As shown in FIG. 12, each of the lead-out structures 912 is coupled to the at least one signal line 911 through the third connection structure 530, and the third connection structure 530 extends through the first bonding layer 310 and the second bonding layer 320 along the first direction, and is disposed at an interval with the first connection structure 510.

For example, the third connection structure 530 has the same structure as the first connection structure, and details are not described herein again.

In some examples, the lead-out structure 912 of the memory area may be non-linear, such as L-shaped or the like. In some other examples, the lead-out structure 912 is linear, and as shown in FIG. 12, the extension direction of the lead-out structure of the memory area in the same interconnection layer intersects with the extension direction of the power line of the first peripheral area, for example, are perpendicular to each other.

The third interconnection layer 220 and the fifth interconnection layer 230 are also provided with lead-out structures. For example, the lead-out structures of the third interconnection layer 220 and the fifth interconnection layer 230 may also be non-linear. Further, the lead-out structures of the third interconnection layer 220 and the fifth interconnection layer 230 may also be linear, and as shown in FIG. 12, in the memory area, the extension directions of the lead-out structures in adjacent interconnection layers intersect, for example, are perpendicular to each other.

In some examples, the extending directions of the signal line 911 and the fourth power line 412 are the same. That is, in the same interconnection layer of the second semiconductor structure 200, the extending direction of the wiring of the driving circuit area and the extending direction of the wiring of the second peripheral area intersect, for example, are perpendicular to each other. The wiring may be a signal line or a power line.

The fourth interconnection layer 420 and the interconnection layer below are also provided with signal lines. For example, in the driving circuit area, signal lines in adjacent interconnection layers intersect, for example, are perpendicular to each other.

An example of the present disclosure further provides a memory system, including: at least one memory device according to any one of the above examples; and a memory controller; the memory controller is coupled to the memory device and is configured to control the memory device to perform an operation.

In the examples of the present disclosure, the memory system may correspond to the memory system in the examples shown in FIG. 1a and FIG. 1b, and the memory controller in the memory system may be independently packaged as a chip, or integrated in another chip, for example, integrated in a north bridge chip or in a host.

An example of the present disclosure further provides an electronic device, including at least one memory device according to any one of the above examples.

In this example of the present disclosure, the electronic device may be understood by referring to the electronic device 10 in FIG. 1a and FIG. 1b, the main memory module 51 in FIG. 2, and the SSD 55 in FIG. 3. Details are not described herein again.

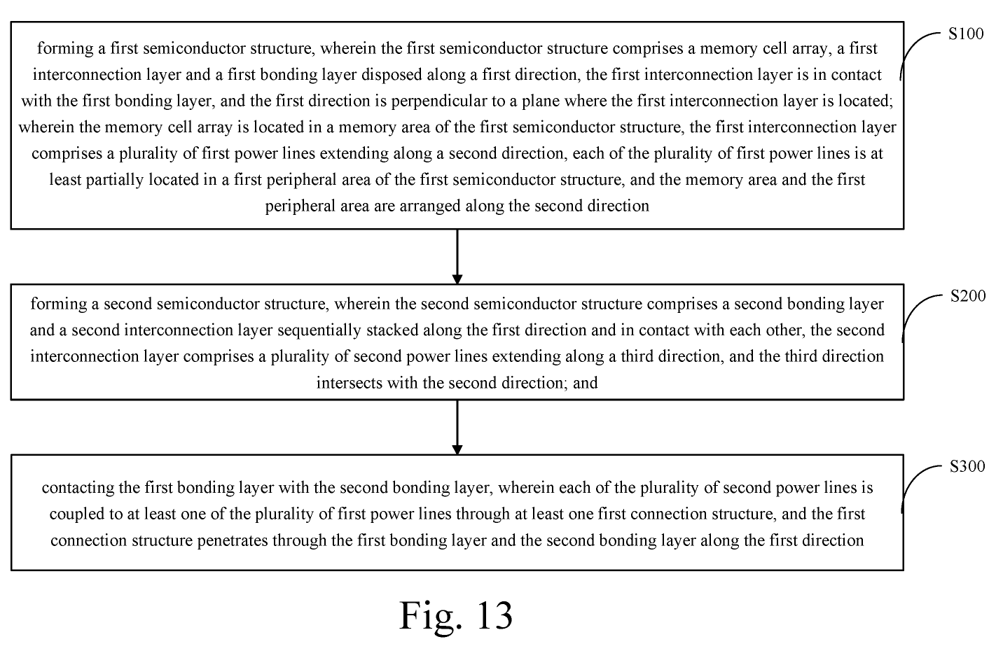

An example of the present disclosure further provides a manufacturing method of a memory device, and FIG. 13 is a schematic flowchart of a method of manufacturing a memory device according to an example of the present disclosure. As shown in FIG. 13, the method may include operations S100, S200, and S300.

At operation S100, the method may include forming a first semiconductor structure; the first semiconductor structure includes a memory cell array, a first interconnection layer and a first bonding layer disposed along a first direction, the first interconnection layer is in contact with the first bonding layer, and the first direction is perpendicular to a plane where the first interconnection layer is located; where the memory cell array is located in a memory area of the first semiconductor structure, the first interconnection layer includes a plurality of first power lines extending along a second direction, each of the plurality of first power lines is at least partially located in a first peripheral area of the first semiconductor structure, and the memory area and the first peripheral area are arranged along the second direction;

At operation S200, the method may include forming a second semiconductor structure; the second semiconductor structure includes a second bonding layer and a second interconnection layer sequentially stacked along the first direction and in contact with each other, the second interconnection layer includes a plurality of second power lines extending along a third direction, and the third direction intersects with the second direction;

At operation S300, the method may include contacting the first bonding layer with the second bonding layer; where each of the plurality of second power lines is coupled to at least one of the plurality of first power lines through at least one first connection structure, and the first connection structure penetrates through the first bonding layer and the second bonding layer along the first direction.

It should be understood that the operations shown in FIG. 13 are not exclusive and other operations may be performed before, after, or between any of the illustrated operations.

In some examples, the first bonding layer includes a plurality of first bonding contacts, and the second bonding layer includes a plurality of second bonding contacts.

In operation S300, contacting the first bonding layer with the second bonding layer, in some example, includes: bonding a plurality of first bonding contacts in the first bonding layer with a plurality of second bonding contacts in the second bonding layer, where each first connection structure includes a first bonding contact and a corresponding second bonding contact, the first bonding contact is in contact with the first power line, and the second bonding contact is in contact with the second power line.

In some examples, the first semiconductor structure includes a first memory area and a second memory area, and a first peripheral area is located between the first memory area and the second memory area.

In the operation S100, forming a first semiconductor structure includes forming, in the first interconnection layer, a first power line penetrating through the first peripheral area along the second direction.

In some examples, forming the first semiconductor structure in operation S100 further includes: forming a third interconnection layer adjacent to the first interconnection layer; where the third interconnection layer includes a plurality of third power lines extending along the third direction that are located in the first peripheral area, the plurality of third power lines are coupled to the plurality of first power lines, the number of the third power lines is less than the number of the first power lines, and the number of the third power lines is less than the number of the second power lines.

In some examples, the second semiconductor structure includes a second peripheral area and a driving circuit area disposed along the second direction, the second peripheral area corresponds to the first peripheral area, and the driving circuit area corresponds to the memory area.

In operation S200, forming the second semiconductor structure includes: forming a second power line located in the second peripheral area in the second interconnection layer.

In some examples, in operation S200, forming the second semiconductor structure further includes: forming a plurality of fourth power lines extending along the second direction in the second interconnection layer; where the fourth power line is at least partially located in the driving circuit area, the fourth power line has a first end and a second end disposed opposite to each other along the second direction, and the first end is close to the second peripheral area.

In operation S300, contacting the first bonding layer with the second bonding layer includes: coupling a first end of the fourth power line with the first power line through the second connection structure; where the second connection structure extends through the first bonding layer and the second bonding layer along the first direction and is disposed at an interval with the first connection structure.

In some examples, the first bonding layer includes a third bonding contact, and the second bonding layer includes a fourth bonding contact; and in operation S300, the contacting the first bonding layer with the second bonding layer includes, for example:

Bonding the third bonding contact in the first bonding layer to the fourth bonding contact in the second bonding layer correspondingly; where the second connection structure includes the third bonding contact and the corresponding fourth bonding contact, the third bonding contact is in contact with the first power line, and the fourth bonding contact is in contact with the fourth power line.

In some examples, in the operation S200, forming the second semiconductor structure further includes: forming a fourth interconnection layer adjacent to the second interconnection layer, where the fourth interconnection layer includes a plurality of fifth power lines extending along the second direction, and the fifth power line is at least partially located in the first peripheral area; and forming a first interconnection access between the fifth power line and the second power line to couple the fifth power line with the second power line.

In some examples, in operation S200, forming the second semiconductor structure further includes: forming a second interconnection access between the first end of the fourth power line and the fifth power line.

For example, the first interconnection access and second interconnection access are formed simultaneously.

In some examples, in operation S200, forming the second semiconductor structure further includes: forming a plurality of sixth power lines extending along the third direction in the fourth interconnection layer, where the sixth power line is located in the driving circuit area; and forming a third interconnection access between the sixth power line and the fourth power line.

For example, the first interconnection access, the second interconnection access, and the third interconnection access are formed simultaneously.

For example, the fifth power line and the sixth power line are formed simultaneously.

For example, the second power line and the fourth power line are formed simultaneously.

In some examples, in operation S200, forming the second semiconductor structure further includes: forming at least one of a sense amplifier, a word line driver, a row decoder and a column decoder in a substrate of the driving circuit area, where the sixth power line is coupled to one of the sense amplifier, the word line driver, the row decoder and the column decoder; and forming a plurality of signal lines in the second interconnection layer; where each signal line is located in the driving circuit area and is coupled to one of the sense amplifier, the word line driver, the row decoder and the column decoder.

In operation S100, forming the first semiconductor structure further includes: forming a plurality of lead-out structures arranged in an array in the first interconnection layer; where each lead-out structure is located in the memory area and is coupled to one bit line or one word line of the memory cell array.

In operation S300, contacting the first bonding layer with the second bonding layer includes: coupling each of the lead-out structures with at least one signal line through a third connection structure; where the third connection structure extends through the first bonding layer and the second bonding layer along the first direction and is disposed at an interval with the first connection structure.

For example, in a sequence, forming a control circuit such as a sense amplifier, a word line driver, a row decoder and a column decoder in the substrate first, and then forming a fifth power line and a sixth power line in the fourth interconnection layer, and next forming a first interconnection access, a second interconnection access and a third interconnection access between the fourth interconnection layer and the second interconnection layer, and then forming a second power line, a fourth power line and a signal line in the second interconnection layer, and finally forming a second bonding layer.

For example, in a sequence, forming a third power line in the third interconnection layer first, then forming a first power line and a lead-out structure in the first interconnection layer and finally forming a first bonding layer.

In some examples, the manufacturing method further includes: forming a plurality of power pads on a side of the first semiconductor structure away from the first bonding layer along the first direction; where the plurality of power pads are coupled to the plurality of first power lines.

In some examples, the manufacturing method further includes: before forming the plurality of power pads, forming a redistribution layer on a side of the memory cell array away from the first bonding layer; where the redistribution layer is disposed in the memory area and the first peripheral area, and is coupled to a first power line in the first interconnection layer located in the first peripheral area;

Forming the plurality of power pads includes: forming a plurality of power pads on a side of the redistribution layer away from the first bonding layer; where the plurality of power pads are coupled to the redistribution layer.

For example, a redistribution layer and a power pad may be formed after operation S300. Also for example, the redistribution layer and the power pad may also be formed after operation S100 and before operation S300.

According to the manufacturing method of the memory device according to the example of the present disclosure, in the structure that the first semiconductor structure and the second semiconductor structure are bonded, the power line in the power supply network along the second direction is formed using the first peripheral area (Array peri Area) of the first semiconductor structure including the memory cell array, so that the power supply network has a larger wiring space, facilitating increasing the number of power lines, increasing the line width, reducing the voltage drop, and improving the power supply network. In addition, the interconnection layer below the second interconnection layer in the second semiconductor structure may have more space to dispose signal lines and data lines, which may increase the line width and the line distance, facilitate shielding between signals, and improve signal quality. Moreover, most of the power line is located in the first semiconductor structure and the upper interconnection layer of the second semiconductor structure reduce the space occupied by the power line in the lower interconnection layer of the second semiconductor structure, facilitate improving the shielding effect between the power line and the signal line. In addition, based on the memory device of the stacked structure, the optimization scheme of the power supply network utilizes the peripheral area of the first semiconductor structure without increasing the chip size.

The above is only a preferred example of the present disclosure, and is not intended to limit the scope of the disclosure of the present disclosure, and any equivalent structural transformation or direct/indirect application made by using the present disclosure and the accompanying drawings is included within the scope of the present disclosure.

What is claimed is:

1. A memory device, comprising:
a first semiconductor structure comprising a memory cell array, a first interconnection layer and a first bonding layer disposed along a first direction, wherein the first interconnection layer is in contact with the first bonding layer, and the first direction is perpendicular to a plane where the first interconnection layer is located; wherein the memory cell array is located in a memory area of the first semiconductor structure, the first interconnection layer comprises first power lines extending along a second direction, each of the first power lines is at least partially located in a first peripheral area of the first semiconductor structure, and the memory area and the first peripheral area are arranged along the second direction;
a second semiconductor structure comprising a second bonding layer and a second interconnection layer sequentially stacked along the first direction and in contact with each other, wherein the second bonding layer is further in contact with the first bonding layer, the second interconnection layer comprises second power lines extending along a third direction, and the third direction intersects with the second direction; and
first connection structures, wherein each of the first connection structures extends through the first bonding layer and the second bonding layer along the first direction, and two ends of each of the first connection structures are connected to the first power line and the second power line respectively.

2. The memory device according to claim 1, wherein a side of the first semiconductor structure away from the first bonding layer is provided with power pads; and
the power pads are coupled to the first power lines.

3. The memory device according to claim 1, wherein:
each of the first connection structures comprises a first bonding contact located in the first bonding layer and a second bonding contact located in the second bonding layer;
the first bonding contact are bonded with the second bonding contact; and
the first bonding contact is in contact with at least one of the first power lines, and the second bonding contact is in contact with at least one of the second power lines.

4. The memory device according to claim 1, wherein:
the first semiconductor structure comprises a first memory area and a second memory area disposed at an interval along the second direction, and the first peripheral area is located between the first memory area and the second memory area; and
the first power line penetrates through the first peripheral area along the second direction.

5. The memory device according to claim 1, wherein:
in the first semiconductor structure, a third interconnection layer adjacent to the first interconnection layer comprises third power lines extending along the third direction and located in the first peripheral area;
the third power lines are coupled to the first power lines; and
a number of the third power lines is less than a number of the first power lines, and the number of the third power lines is less than a number of the second power lines.

6. The memory device according to claim 5, wherein the first semiconductor structure further comprises:
a redistribution layer located between power pads and the memory cell array, wherein the redistribution layer is disposed in the memory area and the first peripheral area and is coupled to the power pads and the third power lines.

7. The memory device according to claim 1, wherein:
the second semiconductor structure comprises a second peripheral area and a driving circuit area arranged along the second direction, the second peripheral area corresponds to the first peripheral area, and the driving circuit area corresponds to the memory area; and
the second power lines are located in the second peripheral area.

8. The memory device according to claim 7, wherein:
the first semiconductor structure comprises a first memory area and a second memory area, and the first peripheral area is located between the first memory area and the second memory area; and
the second semiconductor structure comprises a first driving circuit area and a second driving circuit area, and the second peripheral area is located between the first driving circuit area and the second driving circuit area.

9. The memory device according to claim 7, wherein:
the second interconnection layer further comprises a fourth power line extending along the second direction, and the fourth power line is at least partially located in the driving circuit area;
the fourth power line has a first end and a second end disposed opposite to each other along the second direction, and the first end is close to the second peripheral area; and
the first end is coupled to at least one of the first power lines through a second connection structure, and the second connection structure extends through the first bonding layer and the second bonding layer along the first direction and is disposed at an interval with the first connection structures.

10. The memory device according to claim 9, wherein:
in the second semiconductor structure, a fourth interconnection layer adjacent to the second interconnection layer comprises a fifth power line extending along the second direction;
the fifth power line is at least partially located in the first peripheral area, and the fifth power line is coupled to the second power lines through a first interconnection access; and
the first end of the fourth power line is coupled to the fifth power line through a second interconnection access.

11. The memory device according to claim 10, wherein:
the fourth interconnection layer further comprises:
a sixth power line extending along the third direction and located in the driving circuit area, wherein the sixth power line is coupled to the fourth power line through a third interconnection access; and
at least one of a sense amplifier, a word line driver, a row decoder and a column decoder is disposed in a substrate of the second semiconductor structure and is located in the driving circuit area and coupled to the sixth power line.

12. The memory device according to claim 11, wherein:
the second interconnection layer further comprises signal lines located in the driving circuit area;
each of the signal lines is coupled to one of the sense amplifier, the word line driver, the row decoder and the column decoder;
the first interconnection layer further comprises lead-out structures arranged in an array and located in the memory area;
each of the lead-out structures is coupled to one bit line or one word line of the memory cell array; and
each of the lead-out structures is coupled to at least one of the signal lines through a third connection structure, and the third connection structure extends through the first bonding layer and the second bonding layer along the first direction and is disposed at an interval with the first connection structure.

13. The memory device according to claim 1, wherein the memory cell array comprises a dynamic random access memory cell array.

14. A memory system, comprising:
at least one memory device comprising:
a first semiconductor structure comprising a memory cell array, a first interconnection layer and a first bonding layer disposed along a first direction, wherein the first interconnection layer is in contact with the first bonding layer, and the first direction is perpendicular to a plane where the first interconnection layer is located; wherein the memory cell array is located in a memory area of the first semiconductor structure, the first interconnection layer comprises first power lines extending along a second direction, each of the first power lines is at least partially located in a first peripheral area of the first semiconductor structure, and the memory area and the first peripheral area are arranged along the second direction;
a second semiconductor structure comprising a second bonding layer and a second interconnection layer sequentially stacked along the first direction and in contact with each other, wherein the second bonding layer is further in contact with the first bonding layer, the second interconnection layer comprises second power lines extending along a third direction, and the third direction intersects with the second direction; and
first connection structures, wherein each of the first connection structures extends through the first bonding layer and the second bonding layer along the first direction, and two ends of the each of the first connection structures are connected to the first power line and the second power line respectively; and
a memory controller coupled to the memory device and configured to control the memory device to perform an operation.

15. A method of manufacturing a memory device, comprising:
forming a first semiconductor structure, wherein the first semiconductor structure comprises a memory cell array, a first interconnection layer and a first bonding layer disposed along a first direction, the first interconnection layer is in contact with the first bonding layer, and the first direction is perpendicular to a plane where the first interconnection layer is located; wherein the memory cell array is located in a memory area of the first semiconductor structure, the first interconnection layer comprises first power lines extending along a second direction, each of the first power lines is at least partially located in a first peripheral area of the first semiconductor structure, and the memory area and the first peripheral area are arranged along the second direction;
forming a second semiconductor structure, wherein the second semiconductor structure comprises a second bonding layer and a second interconnection layer sequentially stacked along the first direction and in contact with each other, the second interconnection layer comprises second power lines extending along a third direction, and the third direction intersects with the second direction; and
contacting the first bonding layer with the second bonding layer, wherein each of the second power lines is coupled to at least one of the first power lines through at least one first connection structure, and the first connection structure penetrates through the first bonding layer and the second bonding layer along the first direction.

16. The method according to claim 15, wherein:
the first bonding layer comprises a first bonding contact;
the second bonding layer comprises a second bonding contact; and
the contacting the first bonding layer with the second bonding layer comprises:
bonding the first bonding contact in the first bonding layer to the second bonding contact in the second bonding layer correspondingly, wherein the first connection structure comprises the first bonding contact and the corresponding second bonding contact, the first bonding contact is in contact with at least one of the first power lines, and the second bonding contact is in contact with at least one of the second power lines.

17. The method according to claim 15, wherein:
the first semiconductor structure comprises a first memory area and a second memory area, and the first peripheral area is located between the first memory area and the second memory area; and
the forming a first semiconductor structure comprises:
forming, in the first interconnection layer, the first power lines penetrating through the first peripheral area along the second direction.

18. The method according to claim 15, wherein:
the forming a first semiconductor structure further comprises:
forming a third interconnection layer adjacent to the first interconnection layer,
the third interconnection layer comprises third power lines extending along the third direction and located in the first peripheral area; and
the third power lines are coupled to the first power lines, a number of the third power lines is less than a number of the first power lines, and the number of the third power lines is less than a number of the second power lines.

19. The method according to claim 15, wherein:
the second semiconductor structure comprises a second peripheral area and a driving circuit area disposed along the second direction, the second peripheral area corresponds to the first peripheral area, and the driving circuit area corresponds to the memory area; and
the forming a second semiconductor structure comprises:
forming, in the second interconnection layer, the second power lines located in the second peripheral area; and
forming a fourth power line extending along the second direction in the second interconnection layer, wherein the fourth power line is at least partially located in the driving circuit area, the fourth power line has a first end and a second end disposed opposite to each other along the second direction, and the first end is close to the second peripheral area; and
the contacting the first bonding layer with the second bonding layer comprises:
coupling the first end of the fourth power line with the first power line through a second connection structure, wherein the second connection structure extends through the first bonding layer and the second bonding layer along the first direction and is disposed at an interval with the first connection structure.

20. The method according to claim 19, wherein the forming a second semiconductor structure further comprises:
forming a fourth interconnection layer adjacent to the second interconnection layer, wherein the fourth interconnection layer comprises a fifth power line extending along the second direction, and the fifth power line is at least partially located in the first peripheral area;
forming a first interconnection access between the fifth power line and the second power line;
forming a second interconnection access between the first end of the fourth power line and the fifth power line;
forming a sixth power line extending along the third direction in the fourth interconnection layer, wherein the sixth power line is located in the driving circuit area; and
forming a third interconnection access between the sixth power line and the fourth power line.
